(19) United States
(12) Patent Application Publication
(10) Pub. No.: US 2024/0429284 A1
(43) Pub. Date: Dec. 26, 2024

(54) FORK SHEET DEVICE

(71) Applicant: INTERNATIONAL BUSINESS MACHINES CORPORATION, ARMONK, NY (US)

(72) Inventors: Ruilong Xie, Niskayuna, NY (US); Tsung-Sheng Kang, Ballston Lake, NY (US); Alexander Reznicek, Troy, NY (US); Sagarika Mukesh, ALBANY, NY (US)

(21) Appl. No.: 18/338,383

(22) Filed: Jun. 21, 2023

(51) Int. Cl. H01L 29/08; H01L 27/092; H01L 29/06; H01L 29/417; H01L 29/423; H01L 29/775; H01L 29/786

(52) U.S. Cl. CPC H01L 29/0847; H01L 27/092; H01L 29/0673; H01L 29/41733; H01L 29/42392; H01L 29/775; H01L 29/78696

(57) ABSTRACT

A semiconductor structure including a dielectric bar arranged between and physically separating a first source drain region from a second source drain region, a first silicide liner directly beneath the first source drain region, and second silicide liner directly beneath the second source drain region, where the first silicide liner is a different material than the second silicide liner.

### BACKGROUND

The present invention generally relates to semiconductor structures, and more particularly to fork sheet device structures having dual backside silicide and tight N2P spacing.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a dielectric bar arranged between and physically separating a first source drain region from a second source drain region, a first silicide liner directly beneath the first source drain region, and second silicide liner directly beneath the second source drain region, where the first silicide liner is a different material than the second silicide liner.

According to another embodiment of the present invention, a semiconductor structure is provided. The semiconductor structure may include first nanosheet devices including first source drain regions, second nanosheet devices including second source drain regions, a dielectric bar arranged between and physically separating each of the first source drain regions from each of the second source drain regions, a first silicide liner directly beneath the first source drain regions, and a second silicide liner directly beneath the second source drain regions, where the first silicide liner is a different material than the second silicide liner.

According to another embodiment of the present invention, a semiconductor structure is provided. The semiconductor structure may include n-type nanosheet devices including n-type source drain regions, p-type nanosheet devices including p-type source drain regions, a dielectric bar arranged between and physically separating each of the n-type source drain regions from each of the p-type source drain regions, a first silicide liner directly beneath the first source drain region, and second silicide liner directly beneath the second source drain region, where the first silicide liner is a different material than the second silicide liner.

### BRIEF DESCRIPTION OF THE DRAWINGS

The following detailed description, given by way of example and not intended to limit the invention solely thereto, will best be appreciated in conjunction with the accompanying drawings, in which:

FIGS. 1, 2, and 3 are cross-sectional views of a semiconductor structure during an intermediate step of a method of fabricating a fork sheet device structure according to an exemplary embodiment;

FIGS. 4, 5, and 6 are cross-sectional views of a semiconductor structure after forming a first hard mask according to an exemplary embodiment;

FIGS. 7, 8, and 9 are cross-sectional views of a semiconductor structure after forming sidewall spacers and patterning the nanosheet layers and the substrate according to an exemplary embodiment;

FIGS. 10, 11, and 12 are cross-sectional views of a semiconductor structure after forming dielectric bars according to an exemplary embodiment;

FIGS. 13, 14, and 15 are cross-sectional views of a semiconductor structure after forming shallow trench isolation regions according to an exemplary embodiment;

FIGS. 16, 17, and 18 are cross-sectional views of a semiconductor structure after forming and patterning a sacrificial gate dielectric and sacrificial gates, forming gate spacers, removing portions of the nanosheet stacks, and forming inner spacers according to an exemplary embodiment;

FIGS. 19, 20, and 21 are cross-sectional views of a semiconductor structure after forming a sacrificial liner, forming a patterning mask, and removing portions of the sacrificial liner selective to the patterning mask according to an exemplary embodiment;

FIGS. 22, 23, and 24 are cross-sectional views of a semiconductor structure after forming sacrificial placeholders according to an exemplary embodiment;

FIGS. 25, 26, and 27 are cross-sectional views of a semiconductor structure after removing the sacrificial liner, and forming first source drain regions, second source drain regions, and a dielectric layer according to an exemplary embodiment;

FIGS. 28, 29, and 30 are cross-sectional views of a semiconductor structure after forming gate structures, source drain contacts, forming the middle-of-line and back-end-of-line, and attaching the carrier wafer according to an exemplary embodiment;

FIGS. 31, 32, and 33 are cross-sectional views of a semiconductor structure after flipping the assembly and recessing the substrate according to an exemplary embodiment;

FIGS. 34, 35, and 36 are cross-sectional views of a semiconductor structure after removing remaining portions of the substrate according to an exemplary embodiment;

FIGS. 37, 38, and 39 are cross-sectional views of a semiconductor structure after forming a backside dielectric layer according to an exemplary embodiment;

FIGS. 40, 41, and 42 are cross-sectional views of a semiconductor structure after forming a first backside mask according to an exemplary embodiment;

FIGS. 43, 44, and 45 are cross-sectional views of a semiconductor structure after removing a first portion of the sacrificial placeholders to create a first backside trench according to an exemplary embodiment;

FIGS. 46, 47, and 48 are cross-sectional views of a semiconductor structure after removing the first backside mask and performing a shallow ion implant according to an exemplary embodiment;

FIGS. 49, 50, and 51 are cross-sectional views of a semiconductor structure after forming a first silicide liner, a first adhesion liner, and a first sacrificial fill according to an exemplary embodiment;

FIGS. 52, 53, and 54 are cross-sectional views of a semiconductor structure after removing a second portion of the sacrificial placeholders to create second backside trenches and performing another shallow ion implant according to an exemplary embodiment;

FIGS. 55, 56, and 57 are cross-sectional views of a semiconductor structure after forming a second silicide liner, a second adhesion liner, and a second sacrificial fill according to an exemplary embodiment; and

FIGS. 58, 59, and 60 are cross-sectional views of a semiconductor structure after removing the first sacrificial fill and the second sacrificial fill, forming backside source drain contacts, and forming backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As semiconductor devices continue to decrease in size, it has become desirable to provide distances between the near-most nFET and pFET active regions (i.e., the “N2P space”) on the order of about 8 nanometers (nm) to about 10 nm. Providing N2P spaces at these dimensions can present challenges to communicating with the pFET section and the nFET section. Specifically, N2P spaces on this order reduce the process window within which contact structures connecting the nFET section and pFET section could electrically short with one another. Although the process window can be broadened by positioning the contact structures at locations laterally offset from the N2P space, doing so increases the electrical resistance between the contact structures and the respective pFET section and nFET section, thereby offsetting any improvement in process window and/or electrical characteristics of the multilayer IC device.

The trend to continue reducing the footprint of FET devices has led to the development of forked nanosheet semiconductor devices, also referred to as “fork sheet devices,” A fork sheet device implements nanosheets that are controlled by a tri-gate forked structure. The tri-gate forked structure is realized by forming a dielectric bar or dielectric wall between the P-type and N-type devices. The dielectric bar physically isolates the two adjacent devices from one another, allowing much tighter N2P spacing that facilitates superior area and performance scalability compared to traditional nanosheet devices. However, the scalability achieved by fork sheet devices along with the introduction of the dielectric bar makes it difficult to maximize the source/drain contact area.

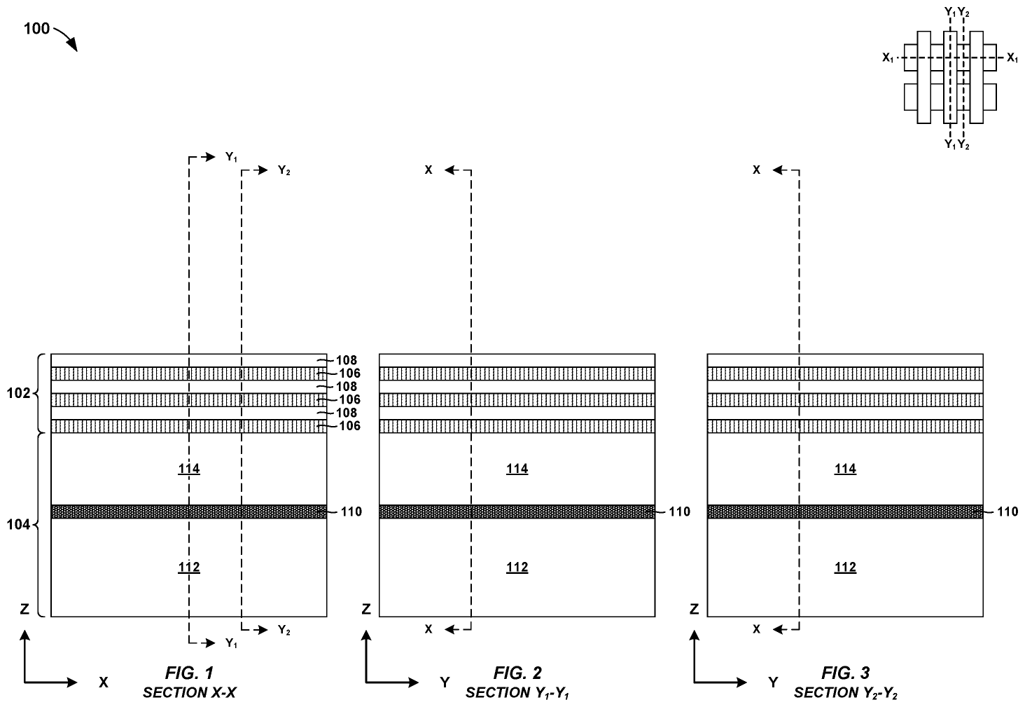

The present invention generally relates to semiconductor structures, and more particularly to fork sheet device structures having dual backside silicide and tight N2P spacing. More specifically, the fork sheet device structures, and associated method disclosed herein enable a novel solution for providing dual backside silicide at very tight N2P spacing without patterning issues or contact-to-contact shorting. Exemplary embodiments of fork sheet device structures having dual backside silicide and tight N2P spacing are described in detail below by referring to the accompanying drawings in FIGS. 1 to 60. Those skilled in the art will readily appreciate that the detailed description given herein with respect to these figures is for explanatory purposes as the invention extends beyond these limited embodiments.

Referring now to FIGS. 1, 2, and 3, a structure 100 is shown during an intermediate step of a method of fabricating a fork sheet device structure according to an embodiment of the invention. FIG. 1 depicts a cross-sectional view of the structure 100 shown in FIGS. 2 and 3 taken along line X-X, FIG. 2 depicts a cross-sectional view of the structure 100 shown in FIG. 1 taken along line Y₁-Y₁, and FIG. 3 depicts a cross-sectional view of the structure 100 shown in FIG. 1 taken along line Y₂-Y₂.

The structure 100 illustrated in FIGS. 1-3 includes nanosheet layers 102 formed on a substrate 104. The nanosheet layers 102 include an alternating series of silicon germanium (SiGe) sacrificial nanosheets 106 (hereinafter “sacrificial nanosheets 106”), silicon (Si) channel nanosheets 108 (hereinafter “channel nanosheets 108”), as illustrated. Although only a limited number of nanosheet layers (102) are shown, one or more additional nanosheet layers and/or nanosheets can optionally be epitaxially grown in an alternating fashion, and the properties of any additional nanosheets are the same as the corresponding nanosheets described herein.

In one or more embodiments, the nanosheet layers 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, the channel nanosheets 108 of the nanosheet layers 102 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 104 may be a layered semiconductor such as a silicon-on-insulator or SiGe-on-insulator, where an etch stop layer 110, separates a base substrate 112 from a top semiconductor layer 114. Unlike conventional layered semiconductor substrates, the etch stop layer 110 of the substrate 104 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure.

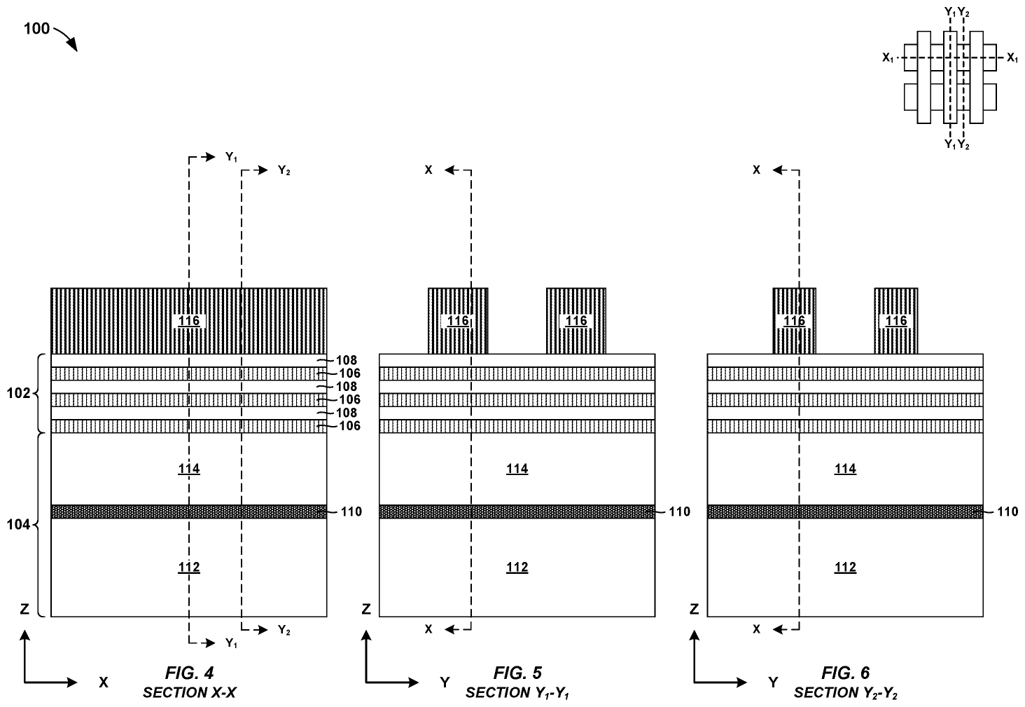

Referring now to FIGS. 4, 5, and 6, the structure 100 is shown after forming a first hard mask 116 according to an embodiment of the invention. FIG. 4 depicts a cross-sectional view of the structure 100 shown in FIGS. 5 and 6 taken along line X-X, FIG. 5 depicts a cross-sectional view of the structure 100 shown in FIG. 4 taken along line Y₁-Y₁, and FIG. 6 depicts a cross-sectional view of the structure 100 shown in FIG. 4 taken along line Y₂-Y₂.

The first hard mask 116 is formed according to known techniques. Specifically, for example, the first hard mask 116 can be formed by first depositing the hard mask material (for example silicon nitride) onto the topmost layer of the nanosheet layers 102 using, for example, chemical vapor deposition (CVD), plasma enhanced CVD (PECVD) or any suitable technique for dielectric deposition that does not induce a physical or chemical change to the topmost layer of the nanosheet layers 102. The hard mask material is subsequently patterned into a plurality of the hard mask 116 or alternatively individual masks. Patterning the hard mask material is commensurate with a desired footprint and location of the fork sheet device structure.

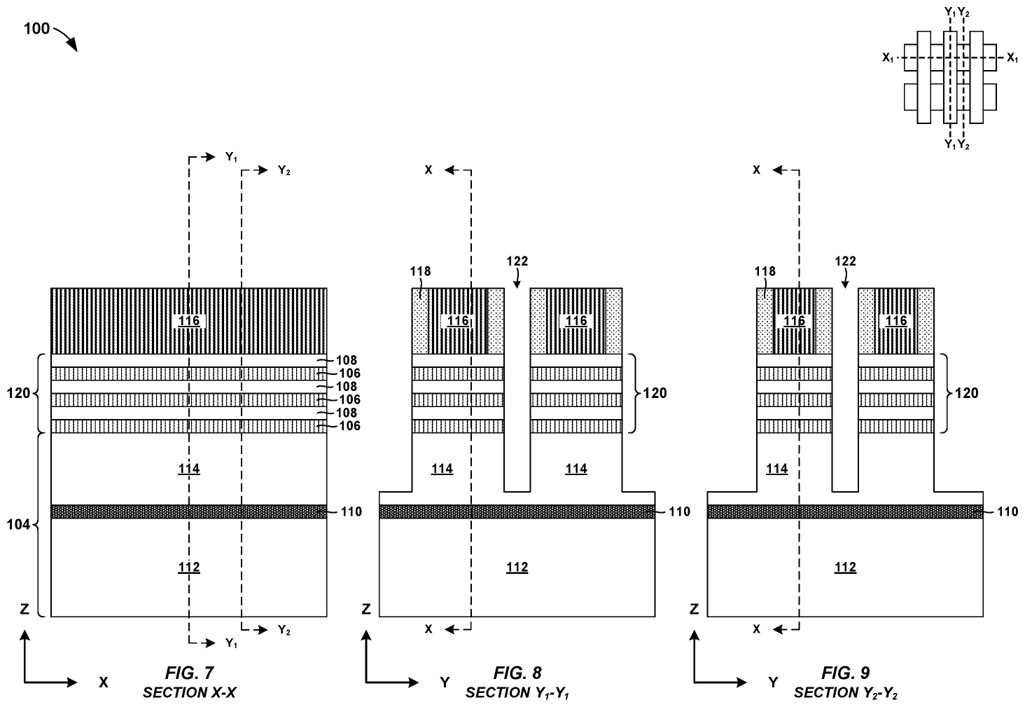

Referring now to FIGS. 7, 8, and 9, the structure 100 is shown after forming sidewall spacers 118 and patterning the nanosheet layers 102 and the substrate 104 according to an embodiment of the invention. FIG. 7 depicts a cross-sectional view of the structure 100 shown in FIGS. 8 and 9 taken along line X-X, FIG. 8 depicts a cross-sectional view of the structure 100 shown in FIG. 7 taken along line Y₁-Y₁, and FIG. 9 depicts a cross-sectional view of the structure 100 shown in FIG. 7 taken along line Y₂-Y₂.

First, a layer of dielectric material may be conformally deposited on top of the structure 100. Specifically, the layer of dielectric material may be deposited directly on the hard mask 116 and exposed surfaces of the nanosheet layers 102. In an embodiment, the layer of dielectric material can include, for example, silicon nitride or silicon oxide, or SiOCN, SiC, TiOx, AlOx, etc. It may be preferable, in some cases, to fabricate the sidewall spacers 118 from a material having a substantially different etch rate than that of the surrounding materials effect good etch selectivity. In an embodiment, the layer of dielectric material may preferably include an oxide, for example, silicon oxide. The layer of dielectric material can be deposited with a conformal deposition technique, using any known atomic layer deposition technique, molecular layer deposition techniques, or other known conformal deposition techniques. In an embodiment, the layer of dielectric material can have a substantially conformal and uniform thickness ranging from about 5 nm to about 20 nm, and ranges there between.

Next, a directional anisotropic etching technique may be used to remove portions of the layer of dielectric material from horizontal surfaces of the structure 100, while leaving it on the sidewalls of the first hard mask 116. For example, a reactive-ion-etching technique may be used to remove portions of the layer of dielectric material from directly above the nanosheet layers 102 and from a top surface of the first hard mask 116. The portions of the layer of dielectric material remaining along opposite sidewalls of the first hard mask 116, form the sidewall spacers 118. Furthermore, the first hard mask 116 and the sidewall spacers 118 should each include materials that would allow the first hard mask 116 to be subsequently removed selective to the sidewall spacers 118. Here, it should also be noted that the sidewall spacers 118 depicted in the figures are for illustration purposes and generally can have a slightly different shape from those shown. For example, the sidewall spacers 118 can have rounded corners which may naturally form during the directional etching process as is known in the art.

The sidewall spacers 118 may have a lateral width ranging substantially equal to the conformal thickness of the layer of dielectric material above. In an embodiment, the lateral width of the sidewall spacers 118 may preferably be sublithographic, or smaller than a lithographic minimum dimension. The term “sublithographic” may refer to a dimension or size less than current dimensions achievable by photolithographic processes, and the term “lithographic” or “lithographic minimum dimension” may refer to a dimension or size equal to or greater than current dimensions achievable by photolithographic processes. The sublithographic and lithographic dimensions may be determined by a person of ordinary skill in the art at the time the application is filed. While a “lithographic minimum dimension” and a “sublithographic dimension” are defined only in relation to a lithography tool and normally change from generation to generation of semiconductor technology, it is understood that the lithographic minimum dimension and the sublithographic dimension are to be defined in relation to the best performance of lithography tools available at the time of semiconductor manufacturing. As of 2015, the lithographic minimum dimension is about 20 nm and is expected to shrink in the future. In an embodiment, for example, the sidewall spacers 118 may have a lateral width ranging from about 5 nm to about 15 nm, and ranges there between. It is possible to adjust spacer width based on etch bias or loss of material during process to meet final technology target dimension. The sidewall spacers 118 define a “fin pattern” or active regions which may subsequently be transferred into underlying layers, including the nanosheet layers 102 and the substrate 104. The first hard mask 116 and the sidewall spacers 118, and the associated process, enables forming two nanosheet stack 120 with small N2P spacing 122 than otherwise possible with typical lithography techniques. According to embodiments of the present invention, the N2P space 122, is less than about 10 nm.

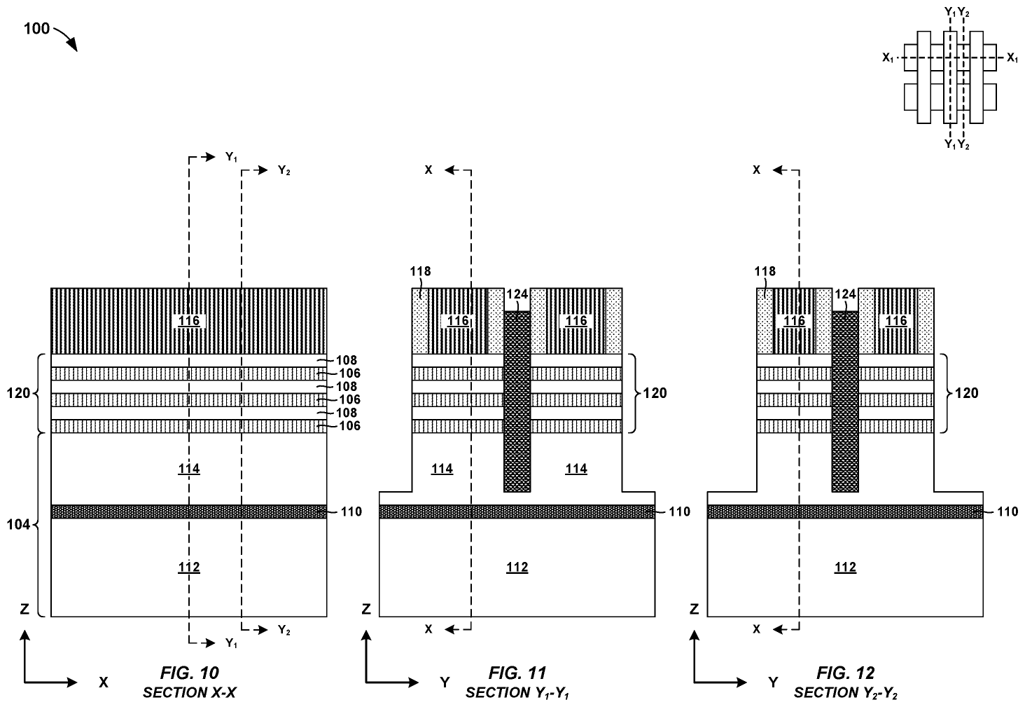

Referring now to FIGS. 10, 11, and 12, the structure 100 is shown after forming dielectric bars 124 according to an embodiment of the invention. FIG. 10 depicts a cross-sectional view of the structure 100 shown in FIGS. 11 and 12 taken along line X-X, FIG. 11 depicts a cross-sectional view of the structure 100 shown in FIG. 10 taken along line Y₁-Y₁, and FIG. 12 depicts a cross-sectional view of the structure 100 shown in FIG. 10 taken along line Y₂-Y₂.

The dielectric bars 124 are formed according to known techniques and as illustrated. The dielectric bars 124 are formed within the N2P space 122 between adjacent nanosheet stacks 120. Specifically, a dielectric material is first deposited to substantially fill the N2P space 122. Next, the dielectric material is selectively etched using an isotropic etch back to recess the dielectric material below top surfaces of the hard mask 116 and the sidewall spacers 118, as illustrated.

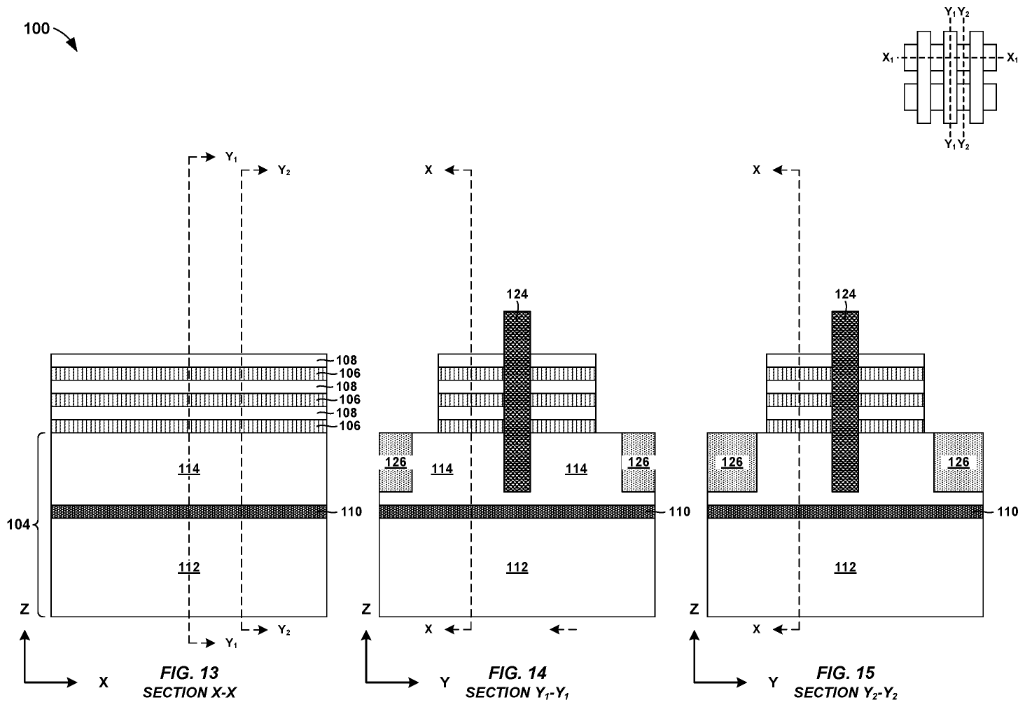

Referring now to FIGS. 13, 14, and 15, the structure 100 is shown after forming shallow trench isolation regions 126 according to an embodiment of the invention. FIG. 13 depicts a cross-sectional view of the structure 100 shown in FIGS. 14 and 15 taken along line X-X, FIG. 14 depicts a cross-sectional view of the structure 100 shown in FIG. 13 taken along line Y₁-Y₁, and FIG. 15 depicts a cross-sectional view of the structure 100 shown in FIG. 13 taken along line Y₂-Y₂.

Shallow trench isolation regions 126 (hereinafter “STI regions 126”) are formed according to known techniques. The STI regions 126 are formed at the bottom of trenches in the substrate 104 formed during patterning of the nanosheet layers 102. Specifically, a dielectric material is deposited at the bottom of trenches in the substrate 104 to isolate adjacent devices from one another according to known techniques. The STI regions 126 may be formed from any appropriate dielectric material including, for example, silicon oxide (SiOₓ) or silicon nitride (SiₓN_{y}).

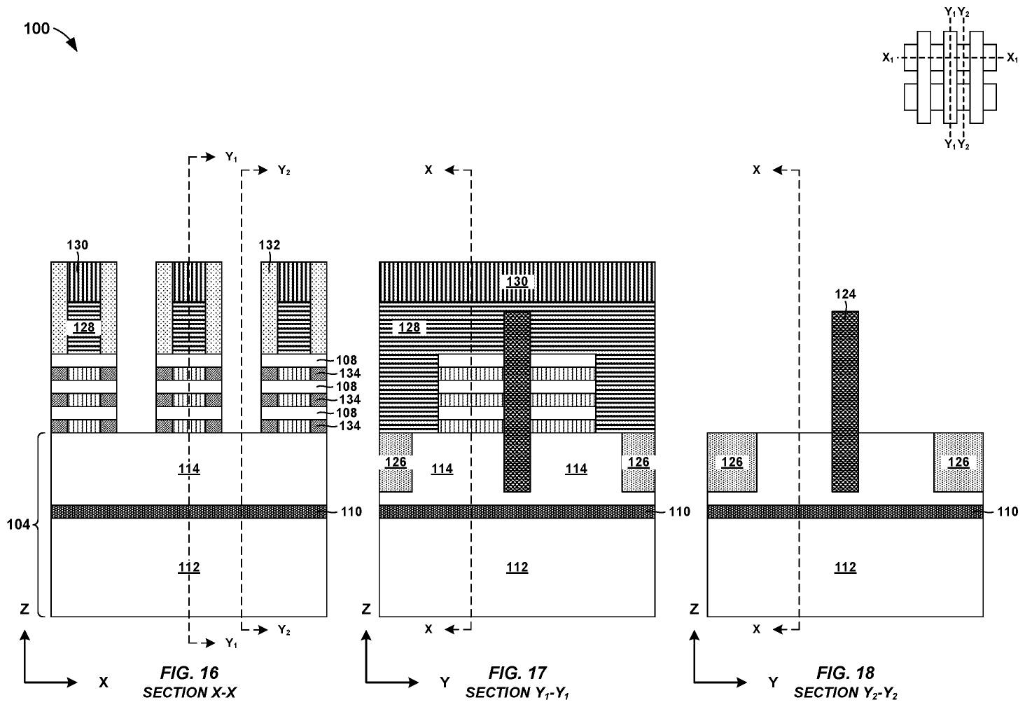

Referring now to FIGS. 16, 17, and 18, the structure 100 is shown after forming and patterning a sacrificial gate dielectric (not shown) and sacrificial gates 128 according to an embodiment of the invention. FIG. 16 depicts a cross-sectional view of the structure 100 shown in FIGS. 16 and 18 taken along line X-X, FIG. 17 depicts a cross-sectional view of the structure 100 shown in FIG. 16 taken along line Y₁-Y₁, and FIG. 18 depicts a cross-sectional view of the structure 100 shown in FIG. 16 taken along line Y₂-Y₂.

The sacrificial gate dielectric is deposited directly on exposed surfaces of the structure 100 according to known techniques. Specifically, for example, a relatively thin layer of silicon oxide (SiO2) is first conformally deposited over and around the nanosheet stacks 120, as illustrated.

The sacrificial gates 128 are blanket deposited over and around the nanosheet stacks 120 according to known techniques. Specifically, for example, a relatively thick layer of amorphous silicon is blanket deposited directly on the sacrificial gate dielectric, as illustrated. In this manner, both the sacrificial gate dielectric and the sacrificial gates 128 completely cover the nanosheet stacks 120, as illustrated.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

Next, a gate hard mask 130 (gate mask 130) is formed over the structure 100. The gate mask 130 defines gate regions of individual devices. According to an exemplary embodiment, the chosen masking material is deposited onto the sacrificial gates 128 and then patterned into a plurality of individual gate masks 130. Next, the pattern created by the individual gate masks 130 is transferred into the sacrificial gate dielectric and the sacrificial gates 128. Specifically, portions of sacrificial gate dielectric and the sacrificial gates 128 are etched or removed selective to the gate masks 130, as illustrated. The portions of the sacrificial gate dielectric and the sacrificial gates 128 can be removed using a silicon RIE process.

With continued reference to FIGS. 16, 17, and 18, the structure 100 is shown after forming gate spacers 132 according to an embodiment of the invention. Next, a spacer material is conformally deposited directly on exposed surfaces of the structure 100 according to known techniques. Specifically, for example, a relatively thin layer of silicon nitride is conformally deposited and then portions of the spacer material are selectively removed or etched from horizontal surfaces according to known techniques. Doing so will generally expose portions of the nanosheet stacks 120, the substrate 104, and the STI regions 126, as illustrated. Remaining portions of the spacer material form the gate spacers illustrated in the figures. In some embodiments, for example, the gate spacers 132 may be composed of SiN, SiBCN, SiOCN, SiOC, or any other combination of low-k materials. The term “low-k” as used throughout the present application denotes a dielectric material that has a dielectric constant of less than 4.0.

With continued reference to FIGS. 16, 17, and 18, the structure 100 is shown after removing portions of the nanosheet stacks 120 according to an embodiment of the invention. Portions of the nanosheet stacks 120 are etched and removed from between the sacrificial gates 128 according to known techniques. Specifically, the pattern created by the gate masks 130 and the gate spacers 132 is transferred into the nanosheet stacks 120. In doing so, portions of the sacrificial nanosheets 106 and the channel nanosheets 108 are removed selective to the gate masks 130 and the gate spacers 132, as illustrated.

In an embodiment, portions of the nanosheet stacks 120 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until the substrate 104 is exposed, as illustrated.

With continued reference to FIGS. 16, 17, and 18, the structure 100 is shown after forming inner spacers 134 according to an embodiment of the invention. First, the sacrificial nanosheets 106 are laterally recessed to make room for the inner spacers 134. In one or more embodiments, the sacrificial nanosheets 106 are laterally recessed using a hydrogen chloride (HCl) gas isotropic etch process, which etches silicon germanium without attacking silicon. In other embodiments, the sacrificial nanosheets 106 are laterally recessed using a ClF3 etch process. Cavities (not shown) are formed by spaces that were occupied by the removed portions of the sacrificial nanosheets 106.

The inner spacers 134 are formed by first conformally depositing a spacer material over the structure 100 to fill the cavities created by laterally recessing the sacrificial nanosheets 106. The conformal spacer material is then isotropically etched to remove all portions except those remaining in the cavities and forming the inner spacers 134. In one or more embodiments, the inner spacers 134 are made from a nitride containing material, for example silicon nitride (SiN). Although inner spacers 134 shown in FIG. 16 are formed from a nitride containing material, they can be formed from any material for which subsequent device fabrication operations are not very selective. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 134 can be selected based on a selectivity of subsequent device fabrication operations for the selected material being below a predetermined threshold.

The inner spacers 134 are positioned such that subsequent etching processes used to remove the sacrificial nanosheets 106 during device fabrication do not also attack subsequently formed source drain regions.

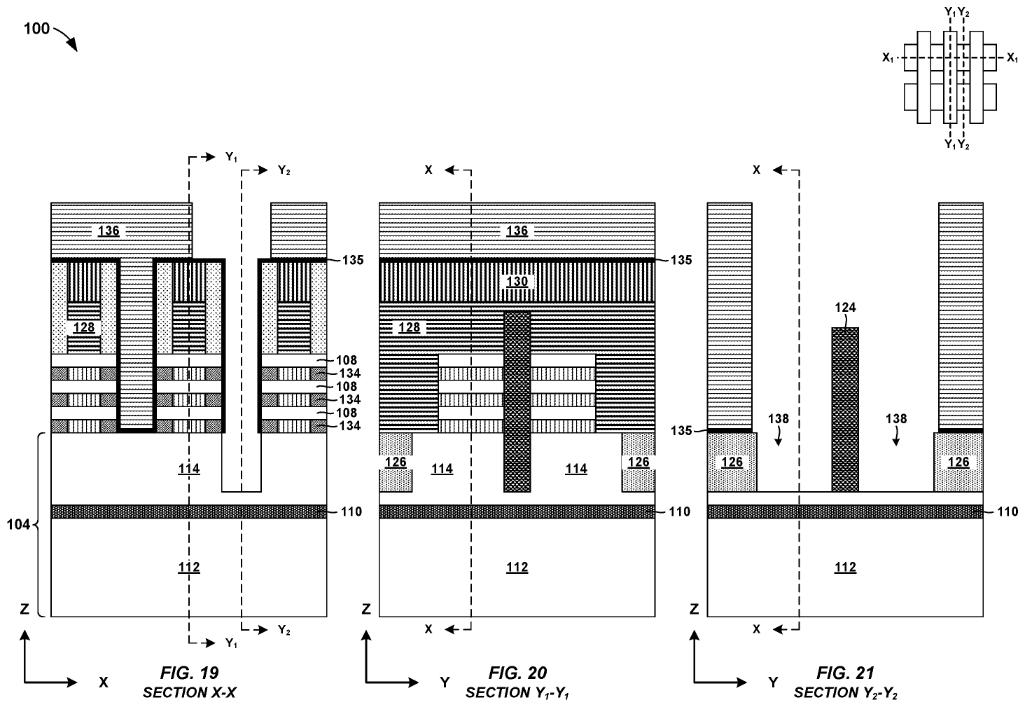

Referring now to FIGS. 19, 20, and 21, the structure 100 is shown after forming a sacrificial liner 135, forming a patterning mask 136, and removing portions of the sacrificial liner 135 selective to the patterning mask 136 according to an embodiment of the invention. FIG. 19 depicts a cross-sectional view of the structure 100 shown in FIGS. 20 and 21 taken along line X-X, FIG. 20 depicts a cross-sectional view of the structure 100 shown in FIG. 19 taken along line Y₁-Y₁, and FIG. 21 depicts a cross-sectional view of the structure 100 shown in FIG. 19 taken along line Y₂-Y₂.

First, the sacrificial liner 135 is conformally deposited directly on exposed surfaces of the structure 100 according to known techniques. Specifically, for example, a relatively thin layer of silicon nitride (SiN) is conformally deposited over and around the nanosheet stacks 120, the sacrificial gates 128, and the gate spacers 132, as illustrated.

Next, the patterning mask 136 is deposited and subsequently patterned to expose certain portions of the structure 100 according to known techniques. Specifically, portions of the sacrificial liner 135 in regions designated for backside source drain contacts are exposed, as illustrated in FIGS. 19 and 21.

The patterning mask 136 can be an organic planarization layer (OPL) or a layer of material that is capable of being planarized or etched by known techniques. In an embodiment, for example, the patterning mask 136 can be an amorphous carbon layer able to withstand subsequent processing temperatures. The patterning mask 136 can preferably have a thickness sufficient to cover existing structures. After deposition of the patterning mask 136, a dry etching technique is applied to pattern the patterning mask 136 according to known techniques.

Next, the portions of the sacrificial liner 135 in regions designated for backside source drain contacts are removed according to known techniques. Specifically, exposed portions of the sacrificial liner 135 are removed using known etching techniques suitable to remove silicon nitride selective to the surrounding materials. In an embodiment, the portions of the sacrificial liner 135 are removed using an anisotropic etch such as, for example, reactive ion etching. In doing so, exposed portions of the dielectric bars 124 may be etched and ultimately recessed or lowered during etching of the sacrificial liner 135, as illustrated in FIG. 21.

Finally, etching continues into the substrate 104. Specifically, exposed portions of the top semiconductor layer 114 are removed according to known techniques, and as illustrated. Doing so forms backside contact trenches 138.

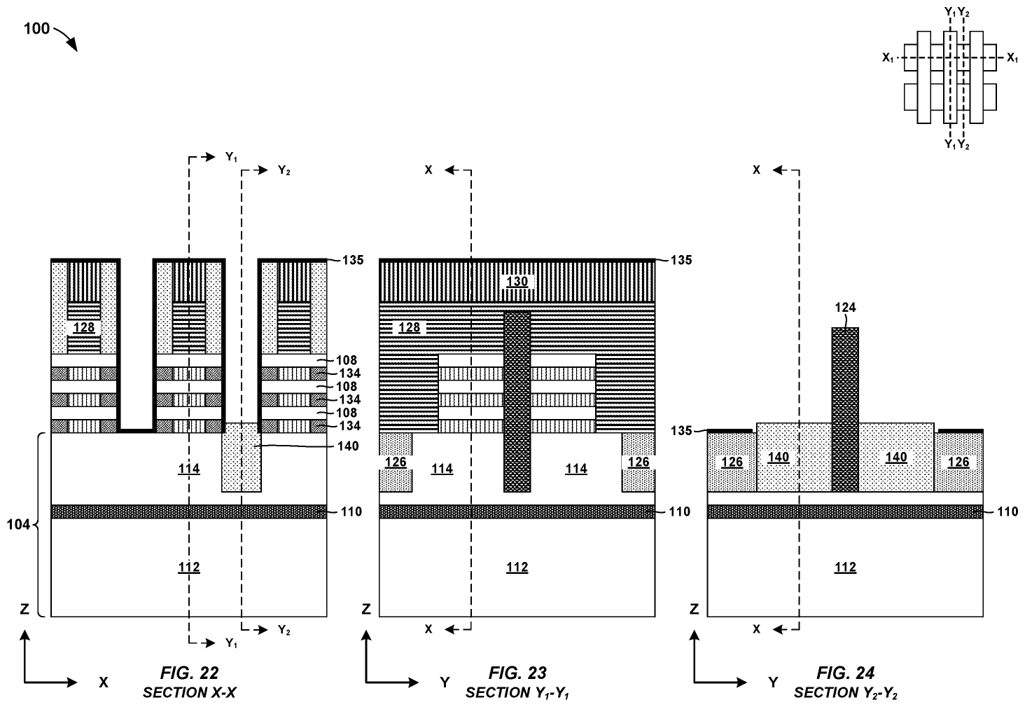

Referring now to FIGS. 22, 23, and 24, the structure 100 is shown after forming sacrificial placeholders 140 according to an embodiment of the invention. FIG. 22 depicts a cross-sectional view of the structure 100 shown in FIGS. 23 and 24 taken along line X-X, FIG. 23 depicts a cross-sectional view of the structure 100 shown in FIG. 22 taken along line Y₁-Y₁, and FIG. 24 depicts a cross-sectional view of the structure 100 shown in FIG. 22 taken along line Y₂-Y₂.

The backside contact trenches 138 are filled with a sacrificial placeholder material according to known techniques. After, the sacrificial placeholder material is recessed to create the sacrificial placeholders 140 according to known techniques. In an embodiment, the sacrificial placeholder material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the channel nanosheets 108. Finally, the sacrificial placeholders 140 can also be referred to as a dielectric sacrificial placeholders 140 or dielectric placeholders 140. Finally, the remaining portions of the patterning mask 136 are removed according to known techniques, for example, by ashing.

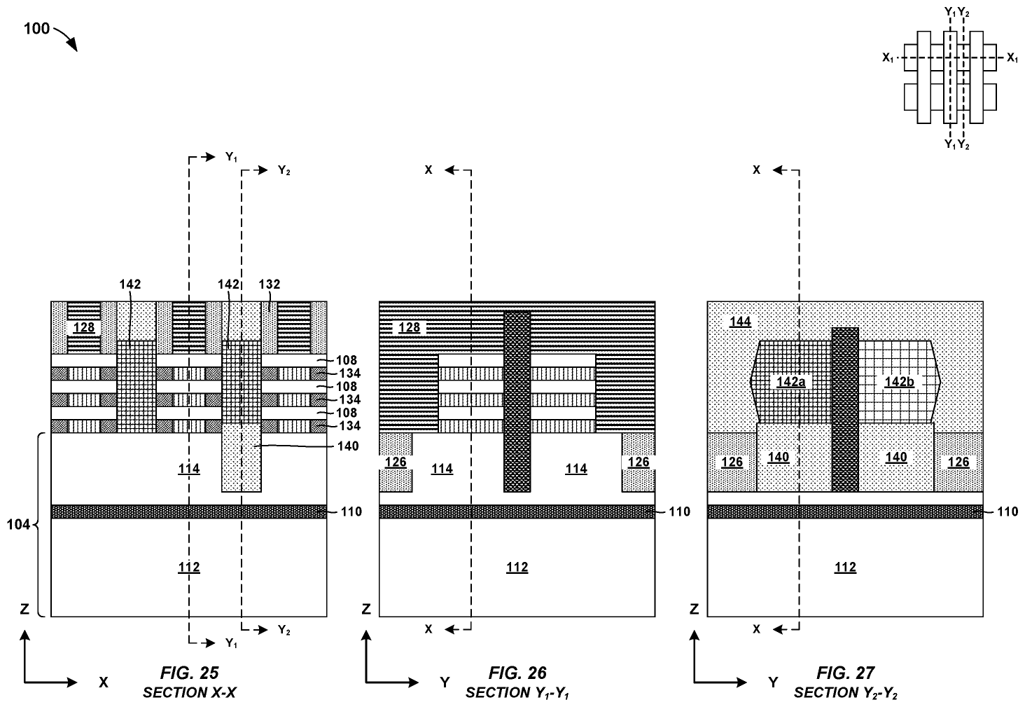

Referring now to FIGS. 25, 26, and 27, the structure 100 is shown after removing the sacrificial liner 135 according to an embodiment of the invention. FIG. 25 depicts a cross-sectional view of the structure 100 shown in FIGS. 26 and 27 taken along line X-X, FIG. 26 depicts a cross-sectional view of the structure 100 shown in FIG. 25 taken along line Y₁-Y₁, and FIG. 27 depicts a cross-sectional view of the structure 100 shown in FIG. 251 taken along line Y₂-Y₂.

First, remaining portions of the sacrificial liner 135 are removed according to known techniques. Specifically, remaining portions of the second sacrificial liner 135 are removed using known etching techniques suitable to remove silicon nitride selective to the surrounding materials. In an embodiment, the remaining portions of the sacrificial liner 135 are removed using an anisotropic etch such as, for example, reactive ion etching.

With continued reference to FIGS. 25, 26, and 27, the structure 100 is shown after forming first source drain regions 142a and second source drain regions 142b according to an embodiment of the invention

The source drain regions 142a, 142b are formed using an epitaxial layer growth process on the exposed ends of the channel nanosheets 106 according to known techniques. Typically, in-situ doping is used to dope the source drain regions 142a, 142b, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, the first source drain regions 142a (on one side of the dielectric bars 124) are of a first-type, for example, P-type, and the second source drain regions 142b (on the opposite side of the dielectric bars 124) are of a second-type, for example, N-type, as illustrated in FIG. 27.

With continued reference to FIGS. 25, 26, and 27, the structure 100 is shown after forming a dielectric layer 144 according to an embodiment of the invention. The dielectric layer 144 is formed by blanket depositing an interlayer dielectric material over the structure 100 according to known techniques. Specifically, the dielectric layer 144 is formed on the source drain regions 142a, 142b and substantially fills the remaining space between adjacent nanosheet stacks 120, as illustrated.

The dielectric layer 144 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 144. Using a self-planarizing dielectric material as the dielectric layer 144 can avoid the need to perform a subsequent planarizing step.

After the dielectric layer 144 is formed, the structure is polished according to known techniques, such as, for example, chemical mechanical polishing techniques. Specifically, the dielectric layer 144, the gate spacers 132, and the gate masks 130 are polished until a topmost surface of the dielectric layer 144 is flush, or substantially flush, with topmost surfaces of the gate spacers 132 and the sacrificial gates 128.

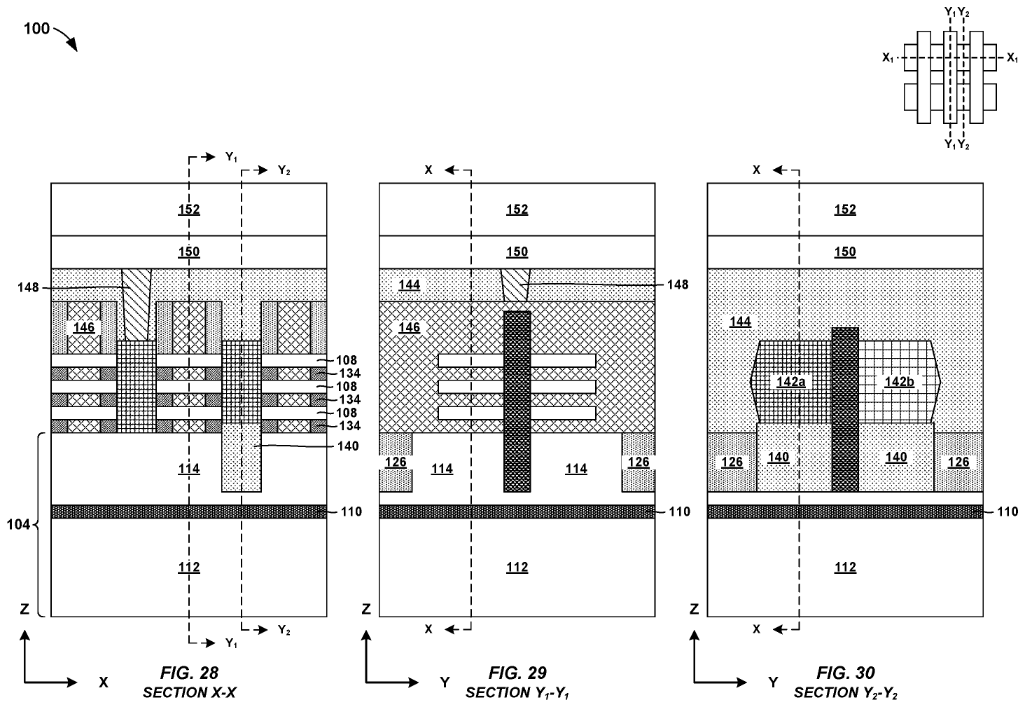

Referring now to FIGS. 28, 29, and 30, the structure 100 is shown after forming gate structures 146 according to an embodiment of the invention. FIG. 28 depicts a cross-sectional view of the structure 100 shown in FIGS. 29 and 30 taken along line X-X, FIG. 29 depicts a cross-sectional view of the structure 100 shown in FIG. 28 taken along line Y₁-Y₁, and FIG. 30 depicts a cross-sectional view of the structure 100 shown in FIG. 28 taken along line Y₂-Y₂.

The sacrificial gates 128 and the sacrificial nanosheets 106 are selectively removed according to known techniques.

First, the sacrificial gates 128 are etched and removed selective to the gate spacers 132 and the nanosheet stacks 120 according to known techniques. Next, the sacrificial nanosheets 106 are etched and removed selective to the channel nanosheets 108 and the inner spacers 134 according to known techniques. Doing so is made possible by the different concentrations of germanium. In this case, the layers with germanium are removed selective to layers without germanium.

Next, the gate structures 146 are formed according to known techniques. First, a gate dielectric (not shown) is conformally deposited directly on exposed surfaces of the structure 100 within the gate cavities or openings and spaces left by removing the sacrificial gates 128 and the sacrificial nanosheets 106 according to known techniques. For example, the gate dielectric is conformally deposited on exposed surfaces of the channel nanosheets 108 and the inner spacers 134.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the first gate dielectric formed within the gate cavities according to known techniques. In at least one embodiment, the work function metal is made of the same conductive material across the entire structure. In at least another embodiment, the first function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium aluminum (TiAl), titanium aluminum carbon (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, gate metal or contact metal, is deposited directly on the work function metal, and fills the gate cavities. The first gate metal may include any suitable conductive material, such as, for example, copper, ruthenium, aluminum, tungsten, cobalt, or alloys thereof. After, excess conductive material can be polished using known techniques.

Finally, additional interlayer dielectric material is deposited according to known techniques. The dielectric layer 144 illustrated in the figures includes the additional interlayer dielectric material.

With continued reference to FIGS. 28, 29, and 30, the structure 100 is shown after forming source drain contacts 148, forming the middle-of-line and back-end-of-line 150, and attaching the carrier wafer 152 according to an embodiment of the invention.

Next, portions of the dielectric layer 44 are removed to expose the source drain regions 142a, 142b. Next, the openings are filled with a conductive material to form the source drain contacts 148 according to known techniques. The source drain contacts 148 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. In some embodiments, the source drain contacts 148 do not contact the gate spacers 132. In other embodiments, the source drain contacts 148 are self-aligned to the gate spacers 132, and thus may be referred to as self-aligned contact structures.

Finally, the middle-of-line and back-end-of-line 150 (hereinafter MOL/BEOL 150) is formed and carrier wafer 152 is secured to a top of the structure 100 according to an embodiment of the invention. After forming the source drain contacts 148, the MOL/BEOL 150 is subsequently formed according to known techniques. Next, the carrier wafer 150 is attached, or removably secured, to the MOL/BEOL 150. In general, and not depicted, the carrier wafer 152 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 152 according to known techniques.

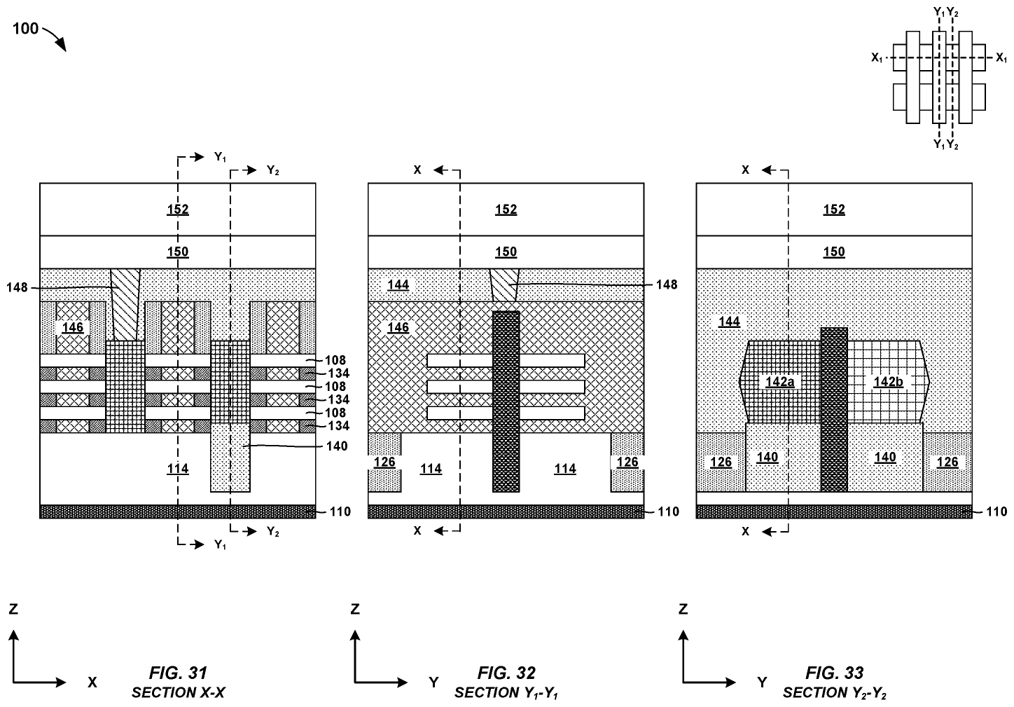

Referring now to FIGS. 31, 32, and 33, the structure 100 is shown after flipping the assembly and recessing the substrate 104 according to an embodiment of the invention. FIG. 31 depicts a cross-sectional view of the structure 100 shown in FIGS. 32 and 33 taken along line X-X, FIG. 32 depicts a cross-sectional view of the structure 100 shown in FIG. 31 taken along line Y₁-Y₁, and FIG. 33 depicts a cross-sectional view of the structure 100 shown in FIG. 31 taken along line Y₂-Y₂.

First, the structure 100 is flipped 180 degrees to prepare for backside processing. In general, backside processing includes fabrication or processing of the structure 100 opposite the active device and wiring layers. Next, the substrate 104 is recessed according to known techniques. Specifically, the base substrate 112 is recessed or completely removed to expose the etch stop layer 110, as shown.

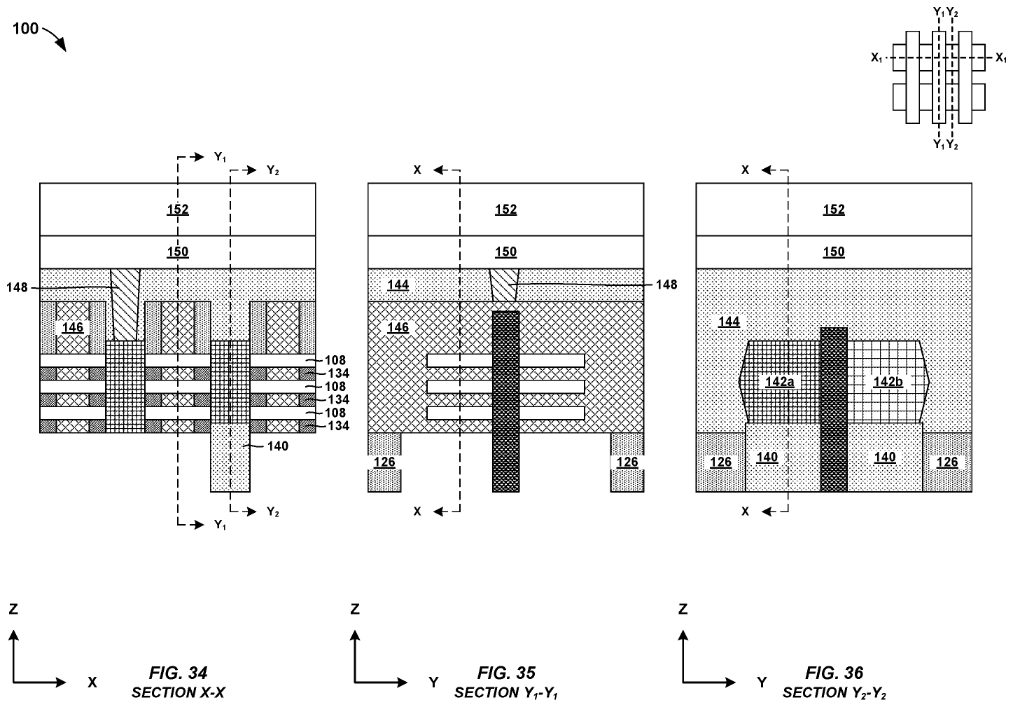

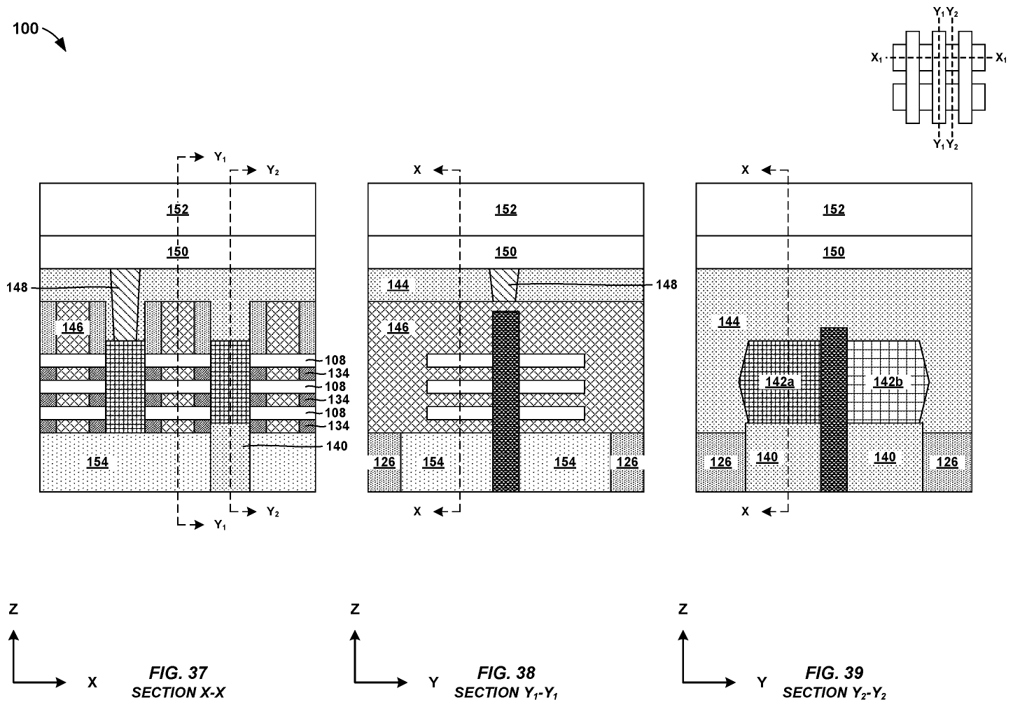

Referring now to FIGS. 34, 35, and 36, the structure 100 is shown after removing remaining portions of the substrate 104 according to an embodiment of the invention. FIG. 34 depicts a cross-sectional view of the structure 100 shown in FIGS. 37 and 38 taken along line X-X, FIG. 35 depicts a cross-sectional view of the structure 100 shown in FIG. 34 taken along line Y₁-Y₁, and FIG. 36 depicts a cross-sectional view of the structure 100 shown in FIG. 34 taken along line Y₂-Y₂.

First, the etch stop layer 110 and the top semiconductor layer 114 are selectively removed according to known techniques. Specifically, the etch stop layer 110 is removed selective to the top semiconductor layer 114, and then the top semiconductor layer 114 is removed selective to the STI regions 126, the sacrificial placeholders 140, the source drain regions 142a, 142b, the dielectric bars 124, and the gate structures 146.

Referring now to FIGS. 37, 38, and 39, the structure 100 is shown after forming a backside dielectric layer 154 according to an embodiment of the invention. FIG. 37 depicts a cross-sectional view of the structure 100 shown in FIGS. 38 and 39 taken along line X-X, FIG. 38 depicts a cross-sectional view of the structure 100 shown in FIG. 37 taken along line Y₁-Y₁, and FIG. 39 depicts a cross-sectional view of the structure 100 shown in FIG. 37 taken along line Y₂-Y₂.

The backside dielectric layer 154 is formed by blanket depositing an interlayer dielectric material over the structure 100 according to known techniques. Specifically, the backside dielectric layer 154 is formed on the source drain regions 142a, 142b and between the STI regions 126 and the dielectric bars 124, as illustrated.

The backside dielectric layer 154 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 154. Using a self-planarizing dielectric material as the backside dielectric layer 154 can avoid the need to perform a subsequent planarizing step.

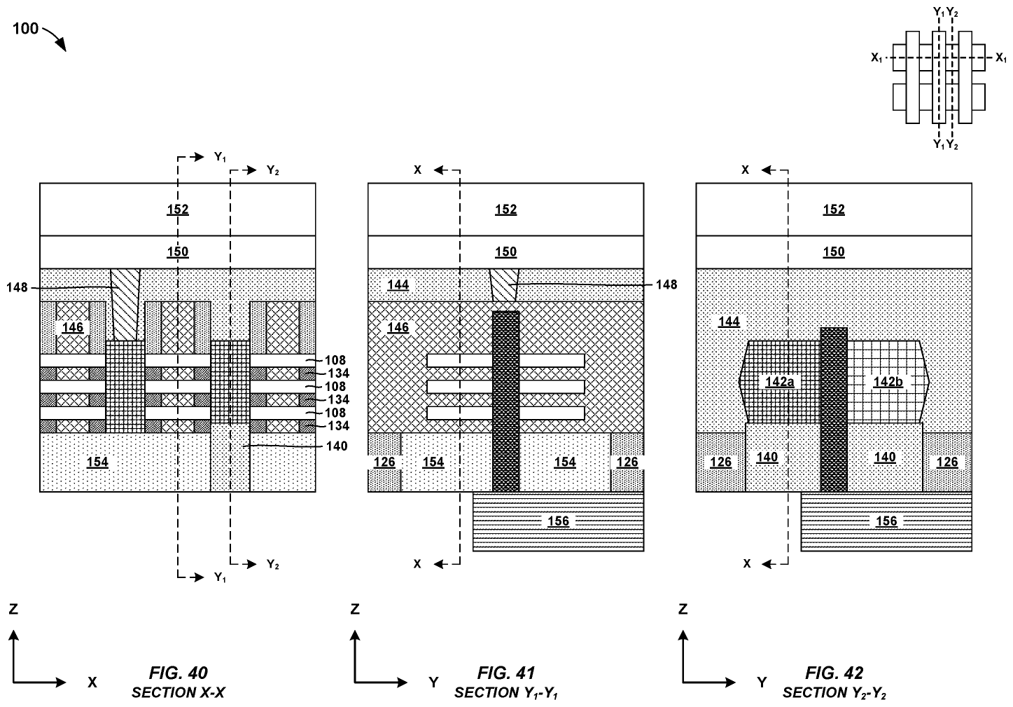

Referring now to FIGS. 40, 41, and 42, the structure 100 is shown after forming a first backside mask 156 according to an embodiment of the invention. FIG. 40 depicts a cross-sectional view of the structure 100 shown in FIGS. 41 and 42 taken along line X-X, FIG. 41 depicts a cross-sectional view of the structure 100 shown in FIG. 41 taken along line Y₁-Y₁, and FIG. 42 depicts a cross-sectional view of the structure 100 shown in FIG. 41 taken along line Y₂-Y₂.

The first backside mask 156 is deposited and subsequently patterned to expose certain portions of the structure 100 according to known techniques. The first backside mask 156 can be an organic planarization layer (OPL) or a layer of material that is capable of being planarized or etched by known techniques. In an embodiment, for example, the first backside mask 156 can be an amorphous carbon layer able to withstand subsequent processing temperatures. The first backside mask 156 can preferably have a thickness sufficient to cover existing structures. After deposition of the first backside mask 156, a dry etching technique is applied to pattern the first backside mask 156 according to known techniques. Specifically, the first backside mask 156 is patterned to expose portions of the structure 100 generally aligned with the first source drain regions 142a on one side of the dielectric bars 124. Some, patterning overlay or misalignment is acceptable so long as portions of the structure 100 generally aligned with the second source drain regions 142b on the other side of the dielectric bars 124 remain covered by the first backside mask 156, as illustrated.

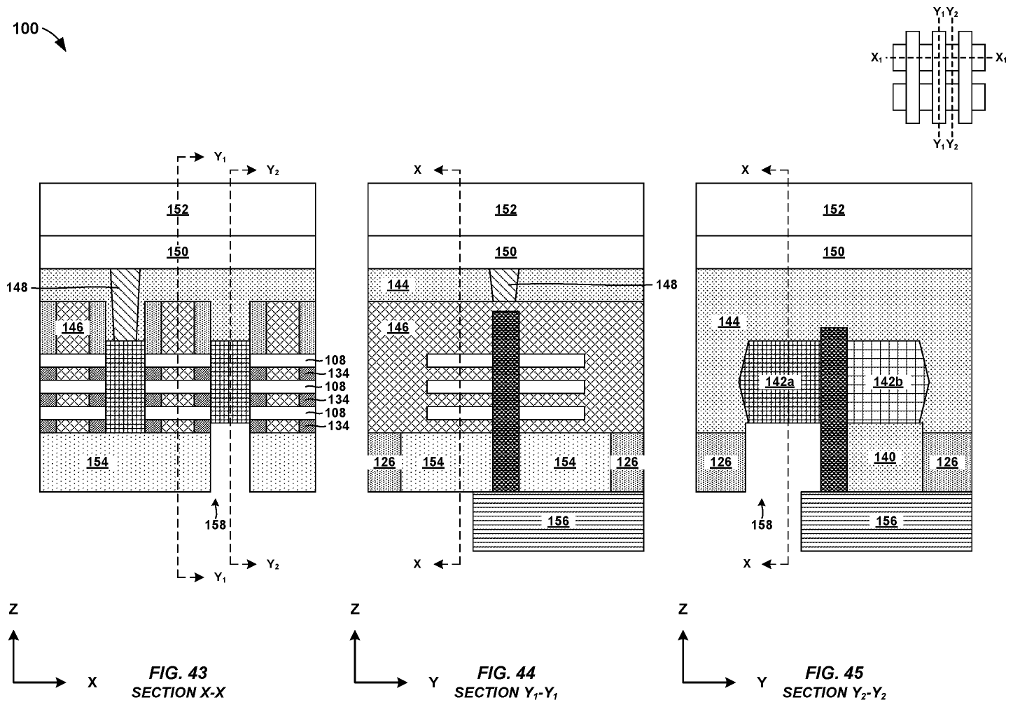

Referring now to FIGS. 43, 44, and 45, the structure 100 is shown after removing a first portion of the sacrificial placeholders 140 to create a first backside trench 158 according to an embodiment of the invention. FIG. 43 depicts a cross-sectional view of the structure 100 shown in FIGS. 44 and 45 taken along line X-X, FIG. 44 depicts a cross-sectional view of the structure 100 shown in FIG. 43 taken along line Y₁-Y₁, and FIG. 45 depicts a cross-sectional view of the structure 100 shown in FIG. 43 taken along line Y₂-Y₂.

The first portion of the sacrificial placeholders 140 is selectively removed according to known techniques. Specifically, the first portion of the sacrificial placeholders 140 is etched or removed selective to the STI regions 126, the dielectric bars 124, and the first source drain regions 142a. For example, anisotropic etching techniques such as, for example, reactive ion etching can be used to remove the first portion of the sacrificial placeholders 140. The first backside trench 158 is created by removing the first portion of the sacrificial placeholders 140. Critically, portions of the first source drain regions 142a are exposed by the first backside trench 158, as illustrated.

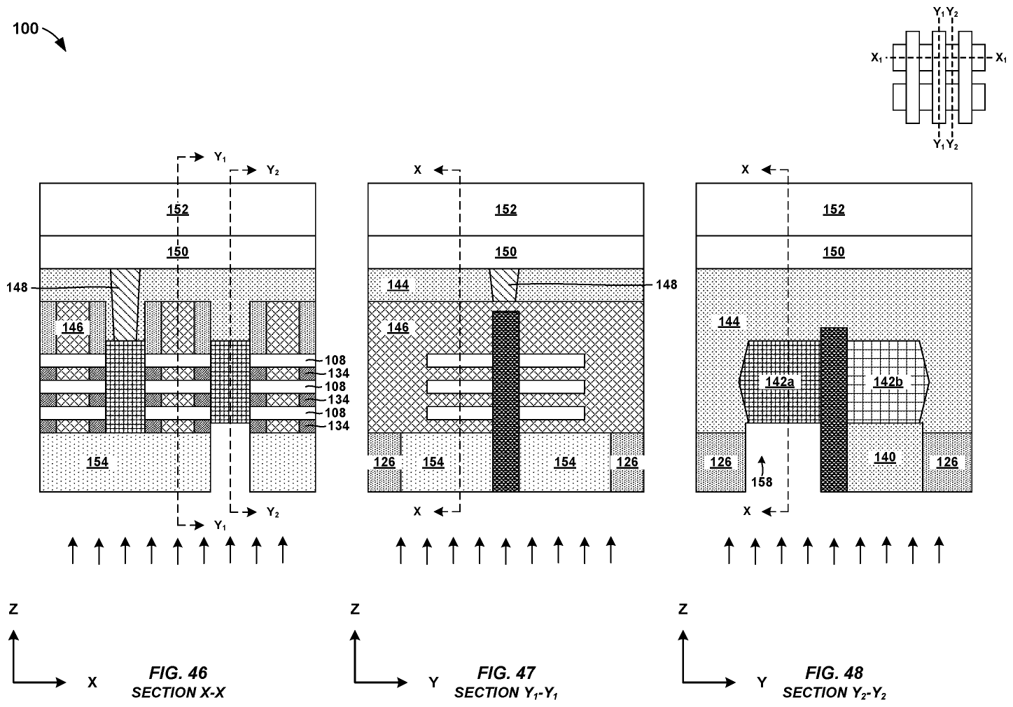

Referring now to FIGS. 46, 47, and 48, the structure 100 is shown after removing the first backside mask 156 and performing a shallow ion implant according to an embodiment of the invention. FIG. 46 depicts a cross-sectional view of the structure 100 shown in FIGS. 47 and 48 taken along line X-X, FIG. 47 depicts a cross-sectional view of the structure 100 shown in FIG. 46 taken along line Y₁-Y₁, and FIG. 48 depicts a cross-sectional view of the structure 100 shown in FIG. 46 taken along line Y₂-Y₂.

First, the remaining portions of the first backside mask 156 are removed according to known techniques, for example, by ashing. Next, a shallow ion implant technique is used to treat exposed surfaces of the first source drain regions 142a and improve contact resistance.

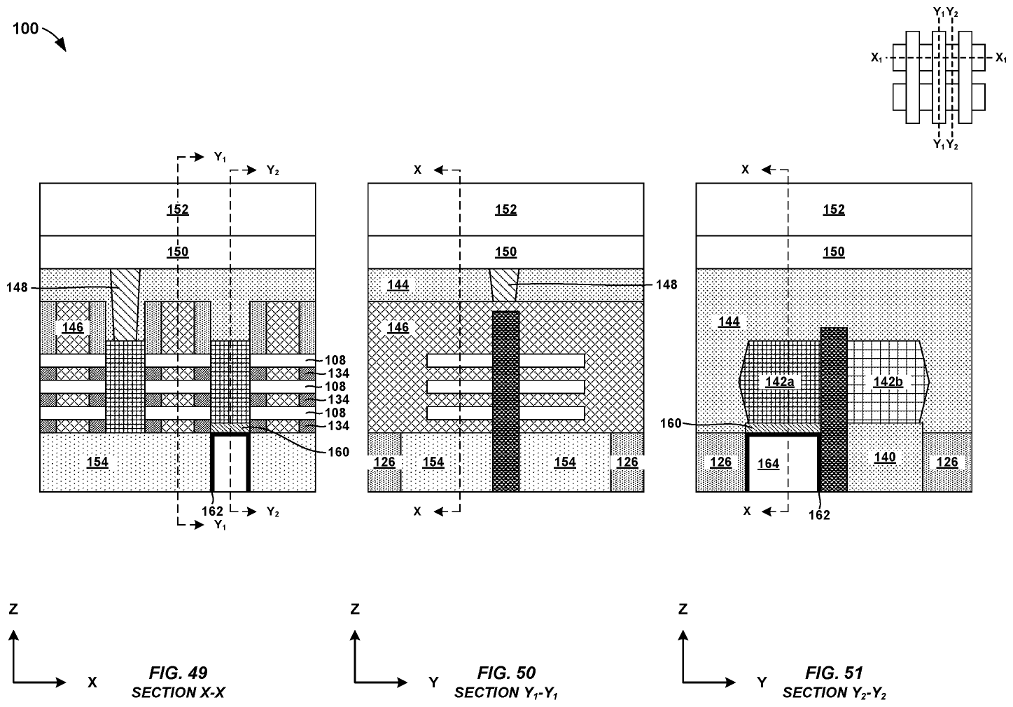

Referring now to FIGS. 49, 50, and 51, the structure 100 is shown after forming a first silicide liner 160, a first adhesion liner 162, and a first sacrificial fill 164 according to an embodiment of the invention. FIG. 49 depicts a cross-sectional view of the structure 100 shown in FIGS. 50 and 51 taken along line X-X, FIG. 50 depicts a cross-sectional view of the structure 100 shown in FIG. 49 taken along line Y₁-Y₁, and FIG. 51 depicts a cross-sectional view of the structure 100 shown in FIG. 49 taken along line Y₂-Y₂.

First, the first silicide liner 160 is deposited within the first backside trench 158 according to known techniques. For example, a directional deposition technique, such as physical vapor deposition, may be preferred to limit deposition of the first silicide liner 160 on vertical, or substantially vertical, sidewalls. Although disposition thickness tolerance of the first silicide liner 160 is not critical, it is necessary for the first silicide liner 160 to have a sufficient thickness, in the z-direction, to enable adequate silicide formation during subsequent processing. The first silicide liner 160 may include any metal or combination of metals suitable for silicide formation at a bottom surface of the first source drain regions 142a, as illustrated. In an embodiment, the first silicide liner 160 is made from titanium, nickel, cobalt, and nickel platinum. Additional processing may be used to remove excess material of the first silicide liner 160 according to known techniques.

Next, the first adhesion liner 162 is deposited within the first backside trench 158 according to known techniques. Specifically, a relatively thin layer of titanium nitride, or other suitable material, is conformally deposited to improve adhesion of subsequently deposited materials.

Next, the first sacrificial fill 164 is deposited within the first backside trench 158 according to known techniques. Specifically, a sacrificial material is deposited directly on top of the first adhesion liner 162 and fills the first backside trench 158, as illustrated. According to embodiments of the present invention, the first sacrificial fill 164 may be amorphous silicon, or other suitable material which may be subsequently selectively removed.

Finally, excess material of the first adhesion liner 162 and the first sacrificial fill 164 is removed according to known techniques, such as, for example, chemical mechanical polishing. Specifically, the first adhesion liner 162 and the first sacrificial fill 164 are polished until flush or substantially flush with the STI regions 126, the dielectric bars 124, as illustrated.

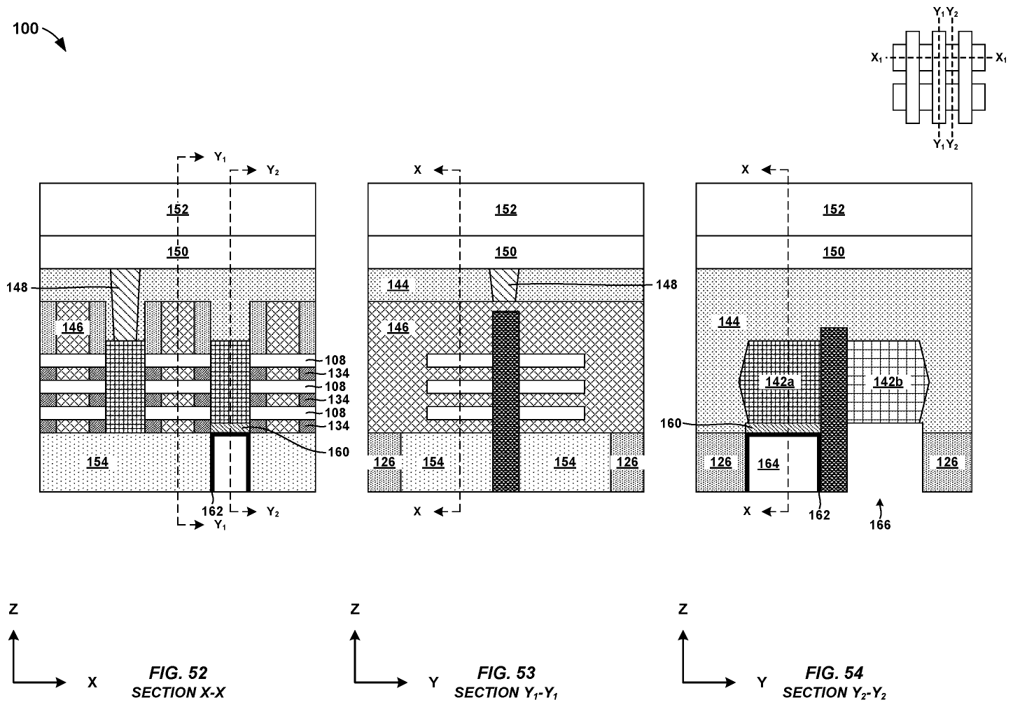

Referring now to FIGS. 52, 53, and 54, the structure 100 is shown after removing a second portion of the sacrificial placeholders 140 to create second backside trenches 166 and performing another shallow ion implant according to an embodiment of the invention. FIG. 52 depicts a cross-sectional view of the structure 100 shown in FIGS. 53 and 54 taken along line X-X, FIG. 53 depicts a cross-sectional view of the structure 100 shown in FIG. 52 taken along line Y₁-Y₁, and FIG. 54 depicts a cross-sectional view of the structure 100 shown in FIG. 52 taken along line Y₂-Y₂.

The second portion of the sacrificial placeholders 140 is selectively removed according to known techniques. Specifically, the second portion of the sacrificial placeholders 140 is etched or removed selective to the STI regions 126, the dielectric bars 124, and the second source drain regions 142b. For example, anisotropic etching techniques such as, for example, reactive ion etching can be used to remove the second portion of the sacrificial placeholders 140. The second backside trenches 166 are created by removing the second portion of the sacrificial placeholders 140. Critically, portions of the second source drain regions 142b are exposed by the second backside trenches 166, as illustrated.

Like above, another shallow ion implant technique is used to treat exposed surfaces of the second source drain regions 142b and improve contact resistance.

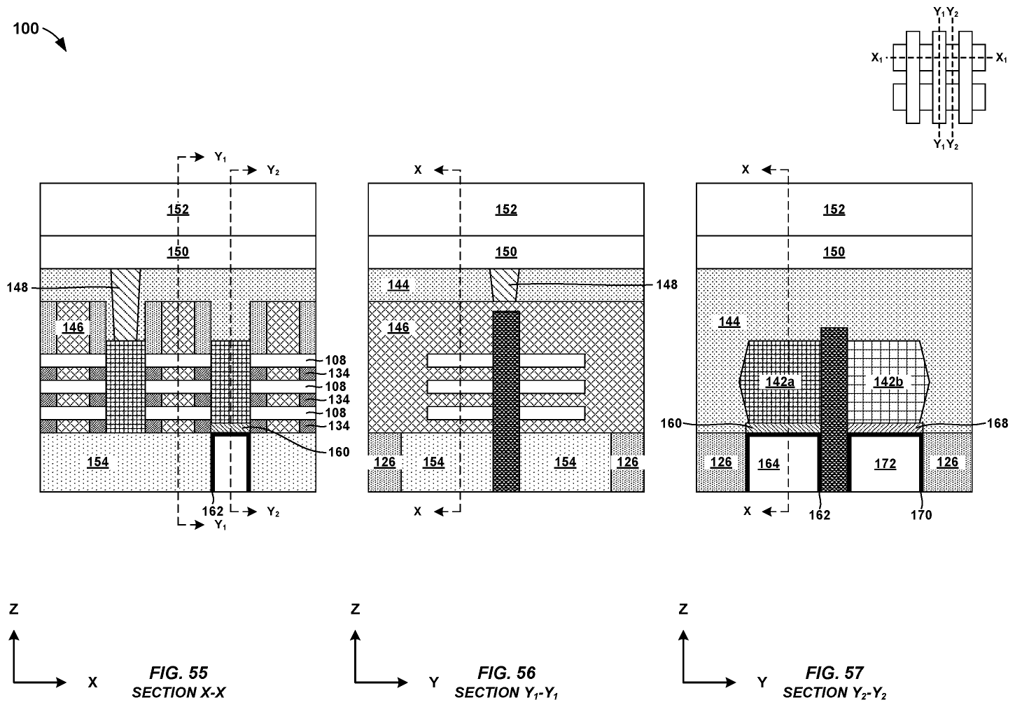

Referring now to FIGS. 55, 56, and 57, the structure 100 is shown after forming a second silicide liner 168, a second adhesion liner 170, and a second sacrificial fill 172 according to an embodiment of the invention. FIG. 55 depicts a cross-sectional view of the structure 100 shown in FIGS. 56 and 57 taken along line X-X, FIG. 56 depicts a cross-sectional view of the structure 100 shown in FIG. 55 taken along line Y₁-Y₁, and FIG. 57 depicts a cross-sectional view of the structure 100 shown in FIG. 55 taken along line Y₂-Y₂.

First, the second silicide liner 168 is deposited within the second backside trenches 166 according to known techniques. For example, a directional deposition technique, such as physical vapor deposition, may be preferred to limit deposition of the second silicide liner 168 on vertical, or substantially vertical, sidewalls. Although disposition thickness tolerance of the second silicide liner 168 is not critical, it is necessary for the second silicide liner 168 to have a sufficient thickness, in the z-direction, to enable adequate silicide formation during subsequent processing. The second silicide liner 168 may include any metal or combination of metals suitable for silicide formation at a bottom surface of the second source drain regions 142b, as illustrated. In an embodiment, the second silicide liner 168 is made from titanium, nickel, cobalt, and nickel platinum. Additional processing may be used to remove excess material of the second silicide liner 168 according to known techniques. In some embodiments, the first silicide liner 160 and the second silicide liner 168 are made from materials specifically tailored to match the source drain region on which they are formed. For example, a titanium silicide liner is typically paired with an N-type source drain region and a nickel platinum silicide liner is typically paired with a P-type source drain region.

Next, the second adhesion liner 170 is deposited within the second backside trenches 166 according to known techniques. Specifically, a relatively thin layer of titanium nitride, or other suitable material, is conformally deposited to improve adhesion of subsequently deposited materials.

Next, the second sacrificial fill 172 is deposited within the second backside trenches 166 according to known techniques. Specifically, a sacrificial material is deposited directly on top of the second adhesion liner 170 and fills the second backside trenches 166, as illustrated. According to embodiments of the present invention, the second sacrificial fill 172 may be amorphous silicon, or other suitable material which may be subsequently selectively removed.

Next, excess material of the second adhesion liner 170 and the second sacrificial fill 172 is removed according to known techniques, such as, for example, chemical mechanical polishing. Specifically, the second adhesion liner 170 and the second sacrificial fill 172 are polished until flush or substantially flush with the STI regions 126, the dielectric bars 124, as illustrated.

Finally, a thermal process, for example an annealing technique, is used to form first silicide regions (not shown) at an interface between the first source drain regions 142a and the first silicide liner 160 and second silicide regions (not shown) at an interface between the second source drain regions 142b and the second silicide liner 168 according to known techniques. Specifically, after the first silicide regions are composed of elements from both the first source drain regions 142a and the first silicide liner 160, and the second silicide regions are composed of elements from both the second source drain regions 142b and the second silicide liner 168.

In an embodiment, for example, the anneal may include subjecting the structure 100 to an elevated temperature ranging from approximately 800° C. to approximately 1250° C., for approximately 1 ns to approximately 500 ms. In yet another embodiment, a high-temperature rapid thermal anneal (RTA) technique may be used, such as, for example, a high temperature spike anneal, or a laser spike anneal. Typically, high temperatures cannot be used at this stage of fabrication due to risk of damaging a gate meal or work function metal; however, in the present case the gate metal or work function metal has not yet been fabricated thus allowing the use of a high temperature anneal.

After the anneal, and critical to the embodiments disclosed herein, portions of the first silicide liner 160 and the second silicide liner 168 will remain in the final structure. It is further noted that a specific annealing step, as described immediately above, is not always necessary. In such cases, the silicides will form during subsequent thermal processing.

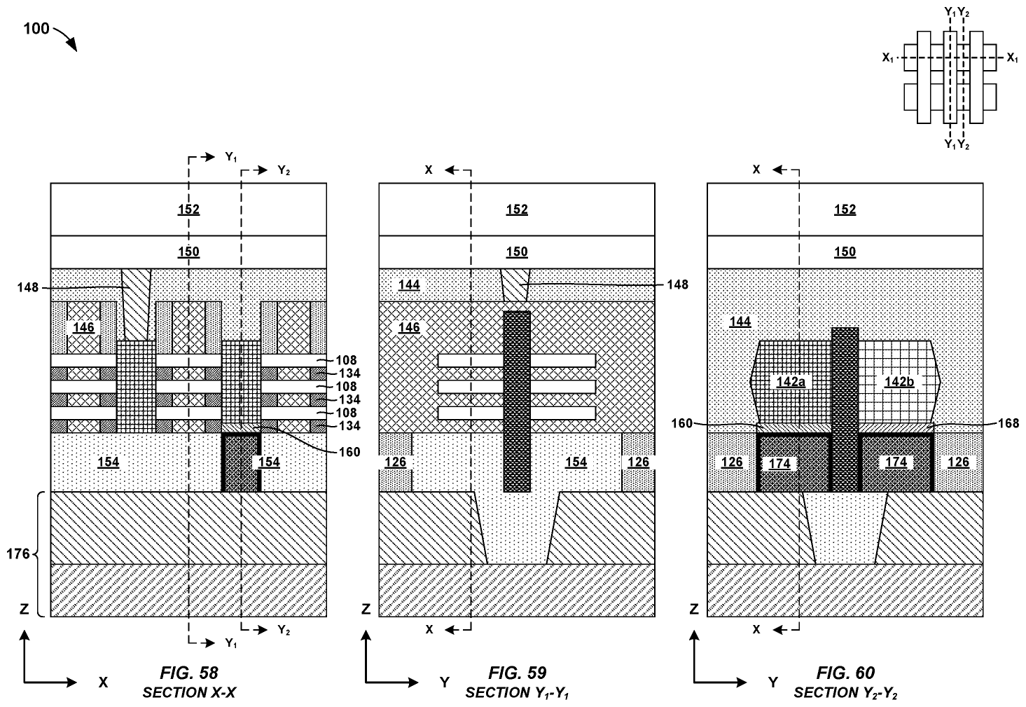

Referring now to FIGS. 58, 59, and 60, the structure 100 is shown after removing the first sacrificial fill 164 and the second sacrificial fill 172, forming backside source drain contacts 174, and forming backside wiring layers 176 according to an embodiment of the invention. FIG. 58 depicts a cross-sectional view of the structure 100 shown in FIGS. 59 and 60 taken along line X-X, FIG. 59 depicts a cross-sectional view of the structure 100 shown in FIG. 58 taken along line Y₁-Y₁, and FIG. 60 depicts a cross-sectional view of the structure 100 shown in FIG. 58 taken along line Y₂-Y₂.

First, both the first sacrificial fill 164 and the second sacrificial fill 172 are recessed and completely removed according to known techniques. Specifically, the first sacrificial fill 164 and the second sacrificial fill 172 are etched selective to the first adhesion liner 162 and second adhesion liner 170.

Next, the openings created by removing the first sacrificial fill 164 and the second sacrificial fill 172 are then filled with a conductive material to form the backside source drain contacts 174 according to known techniques. The backside source drain contacts 174 may include any suitable conductive material, such as, for example, copper, ruthenium, aluminum, tungsten, cobalt, or alloys thereof. In some embodiments, a metal silicide is formed at the bottom of the backside trenches 166 prior to filling them with the conductive material. After, excess conductive material can be polished using known techniques until bottommost surfaces of the backside source drain contacts 174 are flush, or substantially flush, with bottommost surfaces of the STI regions 126 and the backside dielectric layer 154, as illustrated. After forming the backside source drain contacts 174, the backside wiring layers 176 are subsequently formed according to known techniques.

With continued reference to FIGS. 58 and 59, and 60 according to an embodiment, the structure 100 includes a dielectric bar 124 arranged between and physically separating a first source drain region 142a from a second source drain region 142b, a first silicide liner 160 directly beneath the first source drain region 142a, and second silicide liner 168 directly beneath the second source drain region 142b, where the first silicide liner 160 is a different material than the second silicide liner 168.

With continued reference to FIGS. 58 and 59, and 60 according to an embodiment, the structure 100 includes first nanosheet devices including first source drain regions 142a, second nanosheet devices including second source drain regions 142b, a dielectric bar 124 arranged between and physically separating each of the first source drain regions 142a from each of the second source drain regions 142b, a first silicide liner 160 directly beneath the first source drain regions 142a, and a second silicide liner 168 directly beneath the second source drain regions 142b, where the first silicide liner is a different material than the second silicide liner.

With continued reference to FIGS. 58 and 59, and 60 according to an embodiment, the structure 100 includes n-type nanosheet devices including n-type source drain regions 142a, p-type nanosheet devices including p-type source drain regions 142b, a dielectric bar 124 arranged between and physically separating each of the n-type source drain regions 142a from each of the p-type source drain regions 142b, a first silicide liner 160 directly beneath the n-type source drain regions 142a, and second silicide liner directly beneath the p-type source drain regions 142b, where the first silicide liner 160 is a different material than the second silicide liner 168.

With continued reference to FIGS. 58 and 59, and 60, and according to an embodiment, the structure 100 further includes a first silicide arranged between and directly contacting the first source drain region and the first silicide liner, and a second silicide arranged between and directly contacting the second source drain region and the second silicide liner.

With continued reference to FIGS. 58 and 59, and 60, and according to an embodiment, the structure 100 further includes first backside source drain contacts directly beneath and in electrical communication with the first source drain region, and second backside source drain contacts directly beneath and in electrical communication with the second source drain region.

With continued reference to FIGS. 58 and 59, and 60, and according to an embodiment, the structure 100 further includes first backside source drain contacts directly beneath and in electrical communication with the first source drain region, where bottommost surfaces of the first backside source drain contacts are substantially flush with a bottommost surface of the dielectric bar, and second backside source drain contacts directly beneath and in electrical communication with the second source drain region, where bottommost surfaces of the second backside source drain contacts are substantially flush with a bottommost surface of the dielectric bar.

With continued reference to FIGS. 58 and 59, and 60, and according to an embodiment, a distance between the first source drain region and the second source drain region is less than 10 nm.

With continued reference to FIGS. 58 and 59, and 60, and according to an embodiment, a lateral width of the dielectric bar is less than 10 nm.

With continued reference to FIGS. 58 and 59, and 60, and according to an embodiment, sidewalls of the first source drain region and the first silicide liner directly contact a first sidewall of the dielectric bar, and sidewalls of the second source drain region and the second silicide liner directly contact a second sidewall of the dielectric bar.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a dielectric bar arranged between and physically separating a first source drain region from a second source drain region;
a first silicide liner directly beneath the first source drain region; and
second silicide liner directly beneath the second source drain region, wherein the first silicide liner is a different material than the second silicide liner.

2. The semiconductor structure according to claim 1, further comprising:
a first silicide arranged between and directly contacting the first source drain region and the first silicide liner; and
a second silicide arranged between and directly contacting the second source drain region and the second silicide liner.

3. The semiconductor structure according to claim 1, further comprising:
first backside source drain contacts directly beneath and in electrical communication with the first source drain region; and
second backside source drain contacts directly beneath and in electrical communication with the second source drain region.

4. The semiconductor structure according to claim 1, further comprising:
first backside source drain contacts directly beneath and in electrical communication with the first source drain region, wherein bottommost surfaces of the first backside source drain contacts are substantially flush with a bottommost surface of the dielectric bar; and
second backside source drain contacts directly beneath and in electrical communication with the second source drain region, wherein bottommost surfaces of the second backside source drain contacts are substantially flush with a bottommost surface of the dielectric bar.

5. The semiconductor structure according to claim 1, wherein a distance between the first source drain region and the second source drain region is less than 10 nm.

6. The semiconductor structure according to claim 1, wherein a lateral width of the dielectric bar is less than 10 nm.

7. The semiconductor structure according to claim 1,
wherein sidewalls of the first source drain region and the first silicide liner directly contact a first sidewall of the dielectric bar,
wherein sidewalls of the second source drain region and the second silicide liner directly contact a second sidewall of the dielectric bar.

8. A semiconductor structure comprising:
first nanosheet devices comprising first source drain regions;
second nanosheet devices comprising second source drain regions;
a dielectric bar arranged between and physically separating each of the first source drain regions from each of the second source drain regions;
a first silicide liner directly beneath the first source drain regions; and
a second silicide liner directly beneath the second source drain regions, wherein the first silicide liner is a different material than the second silicide liner.

9. The semiconductor structure according to claim 8, further comprising:
a first silicide arranged between and directly contacting each of the first source drain regions and the first silicide liner; and
a second silicide arranged between and directly contacting each of the second source drain regions and the second silicide liner.

10. The semiconductor structure according to claim 8, further comprising:
first backside source drain contacts directly beneath and in electrical communication with each of the first source drain regions; and
second backside source drain contacts directly beneath and in electrical communication with each of the second source drain regions.

11. The semiconductor structure according to claim 8, further comprising:
first backside source drain contacts directly beneath and in electrical communication with each of the first source drain regions, wherein bottommost surfaces of the first backside source drain contacts are substantially flush with a bottommost surface of the dielectric bar; and
second backside source drain contacts directly beneath and in electrical communication with each of the second source drain regions, wherein bottommost surfaces of the second backside source drain contacts are substantially flush with a bottommost surface of the dielectric bar.

12. The semiconductor structure according to claim 8, wherein a distance between each of the first source drain regions and each of the second source drain regions is less than 10 nm.

13. The semiconductor structure according to claim 8, wherein a lateral width of the dielectric bar is less than 10 nm.

14. The semiconductor structure according to claim 8,
wherein sidewalls of each of the first source drain regions and the first silicide liner directly contact a first sidewall of the dielectric bar, wherein sidewalls of each of the second source drain regions and the second silicide liner directly contact a second sidewall of the dielectric bar.

15. A semiconductor structure comprising:
n-type nanosheet devices comprising n-type source drain regions;
p-type nanosheet devices comprising p-type source drain regions;
a dielectric bar arranged between and physically separating each of the n-type source drain regions from each of the p-type source drain regions;
a first silicide liner directly beneath the n-type source drain regions; and
second silicide liner directly beneath the p-type source drain regions, wherein the first silicide liner is a different material than the second silicide liner.

16. The semiconductor structure according to claim 15, further comprising:
a first silicide arranged between and directly contacting the n-type source drain regions and the first silicide liner; and
a second silicide arranged between and directly contacting the p-type source drain regions and the second silicide liner.

17. The semiconductor structure according to claim 15, further comprising:
first backside source drain contacts directly beneath and in electrical communication with the n-type source drain regions; and
second backside source drain contacts directly beneath and in electrical communication with the p-type source drain regions.

18. The semiconductor structure according to claim 15, wherein a distance between each of the n-type source drain regions and each of the p-type source drain regions is less than 10 nm.

19. The semiconductor structure according to claim 15, wherein a lateral width of the dielectric bar is less than 10 nm.

20. The semiconductor structure according to claim 15,
wherein sidewalls of the n-type source drain regions and the first silicide liner directly contact a first sidewall of the dielectric bar,
wherein sidewalls of the p-type source drain regions and the second silicide liner directly contact a second sidewall of the dielectric bar.
